(19) United States
(12) Patent Application Publication
(10) Pub. No.: US 2026/0129788 A1
(43) Pub. Date: May 7, 2026

(54) MOTHERBOARD STRUCTURE AND ELECTRONIC DEVICE

(71) Applicant: ASRock Industrial Computer Corporation, Taipei City (TW)

(72) Inventor: Yi-Kang CHEN, Taipei City (TW)

(21) Appl. No.: 18/940,047

(22) Filed: Nov. 7, 2024

(30) Foreign Application Priority Data
Jan. 30, 2024 (TW) 113201110

(51) Int. Cl. H05K 7/20; G06F 1/20; H05K 7/14

(52) U.S. Cl. CPC H05K 7/20145; G06F 1/20; H05K 7/1429; H05K 7/20163; H05K 7/20172; H05K 7/20427; H05K 7/20509; H05K 7/20518; G06F 2200/201

(57) ABSTRACT

The present invention discloses a motherboard structure and an electronic device. The motherboard structure includes a circuit substrate, a processor, at least one adapter, at least one external card, and a heat dissipation module. The processor is arranged at the circuit substrate. The adapter is arranged at the circuit substrate, and includes a slot facing the processor. The external card is inserted into the slot, and the external card and the circuit substrate collectively define an opening facing the processor. The heat dissipation module is arranged at the processor, and includes a notch facing the opening. The heat dissipation module is adapted to generate an airflow flowing to the opening through the notch.

### CROSS REFERENCE TO RELATED APPLICATIONS

This application claims the priority benefit of Taiwan application serial no. 113201110, filed on Jan. 30, 2024. The entirety of the above-mentioned patent application is hereby incorporated by reference herein and made a part of this specification.

### BACKGROUND

### Technical Field

The present invention relates to a motherboard and an electronic device, and in particular, to a motherboard structure having desirable heat dissipation efficiency and an electronic device having the motherboard structure.

### Description of Related Art

An electronic device, for example, a computer, usually includes a computer case and a motherboard arranged in the computer case. The motherboard is provided with a considerable quantity of elements, for example, a processor, a memory card, a display card, a resistor, and a capacitor. Some elements generate a considerable amount of heat during operation. To quickly dissipate the generated heat to outside, a heat dissipation module is usually mounted to perform heat dissipation. For example, a heat dissipation module including a fan is mounted to a central processing unit (CPU) to perform heat dissipation.

However, due to the limitation of the Intel platform design guide, the element arranged on the motherboard usually has a fixed arrangement direction, and the direction is not adjusted to mate with the heat dissipation module. Even if the heat dissipation module is mounted to assist in the heat dissipation, some elements still have the problem of overtemperature.

### SUMMARY

An objective of the present invention is to provide a motherboard structure and an electronic device, so as to achieve desirable heat dissipation efficiency.

To achieve the above objective, a motherboard structure according to the present invention includes a circuit substrate, a processor, at least one adapter, at least one external card, and a heat dissipation module. The processor is arranged at the circuit substrate. The adapter is arranged at the circuit substrate, and includes a slot facing the processor. The external card is inserted into the slot, and the external card and the circuit substrate collectively define an opening facing the processor. The heat dissipation module is arranged at the processor, and includes a notch facing the opening. The heat dissipation module is adapted to generate an airflow flowing to the opening through the notch.

To achieve the above objective, an electronic device according to the present invention includes a computer case and a motherboard structure. The motherboard structure is arranged in the computer case, and includes a circuit substrate, a processor, at least one adapter, at least one external card, and a heat dissipation module. The processor is arranged at the circuit substrate. The adapter is arranged at the circuit substrate, and includes a slot facing the processor. The external card is inserted into the slot, and the external card and the circuit substrate collectively define an opening facing the processor. The heat dissipation module is arranged at the processor, and includes a notch facing the opening. The heat dissipation module is adapted to generate an airflow flowing to the opening through the notch.

Carrying on with the above, in the motherboard structure and the electronic device of the present invention, the adapter is arranged at the circuit substrate, and includes the slot facing the processor. The external card is inserted into the slot, and the external card and the circuit substrate collectively define the opening facing the processor. The heat dissipation module is arranged at the processor, and includes the notch facing the opening. The heat dissipation module is adapted to generate the airflow flowing to the opening through the notch. Therefore, the above structural design causes the motherboard structure and the electronic device of the present invention to have desirable heat dissipation efficiency.

### BRIEF DESCRIPTION OF THE DRAWINGS

The disclosure will become more fully understood from the detailed description and accompanying drawings, which are given for illustration only, and thus are not limitative of the present disclosure, and wherein:

FIG. 1 is a schematic diagram of an electronic device according to an embodiment of the present invention.

FIG. 2 and FIG. 3 are respectively a three-dimensional schematic diagram and a schematic top view of a motherboard structure of the electronic device in FIG. 1.

FIG. 4 is a schematic cross-sectional view of the motherboard structure in FIG. 2.

FIG. 5 is a schematic cross-sectional view of an existing motherboard structure.

FIG. 6 is a schematic cross-sectional view of a motherboard structure according to another embodiment of the present invention.

### DETAILED DESCRIPTION

A motherboard structure and an electronic device according to embodiments of the present invention are described below with reference to relevant figures. Same elements are described with same reference numerals. Elements, units, or modules appearing in figures of the following embodiments are merely used for describing relative relationships thereof, and do not represent proportions or sizes of real elements, units, or modules.

The electronic device in the specification may be a desktop computer or a server. In the following embodiments, an example in which the electronic device is a desktop computer is used.

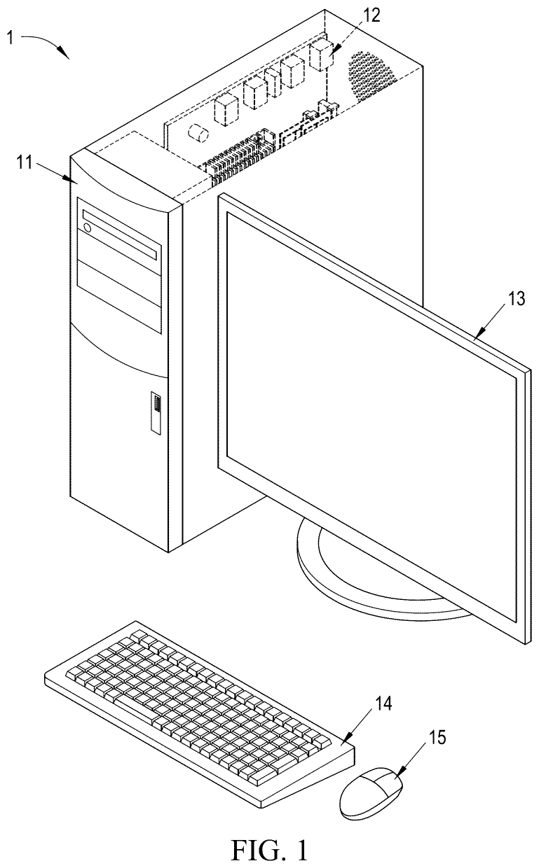

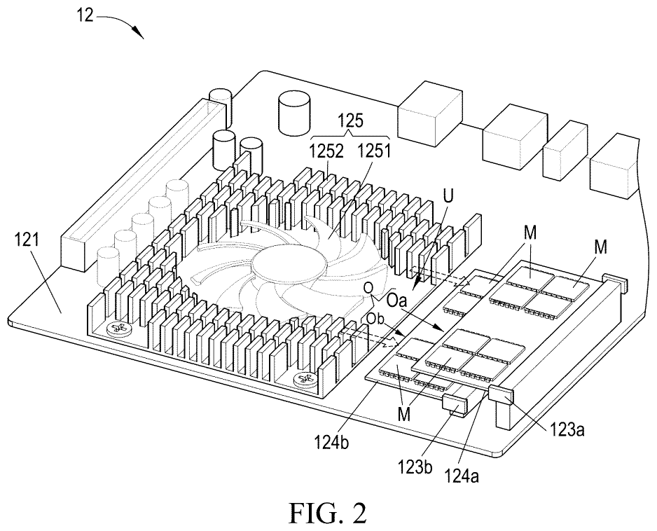

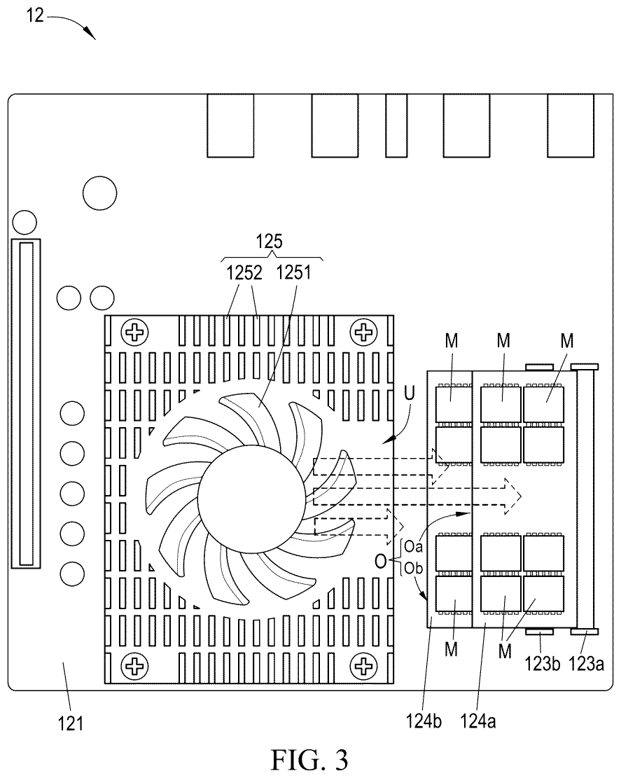

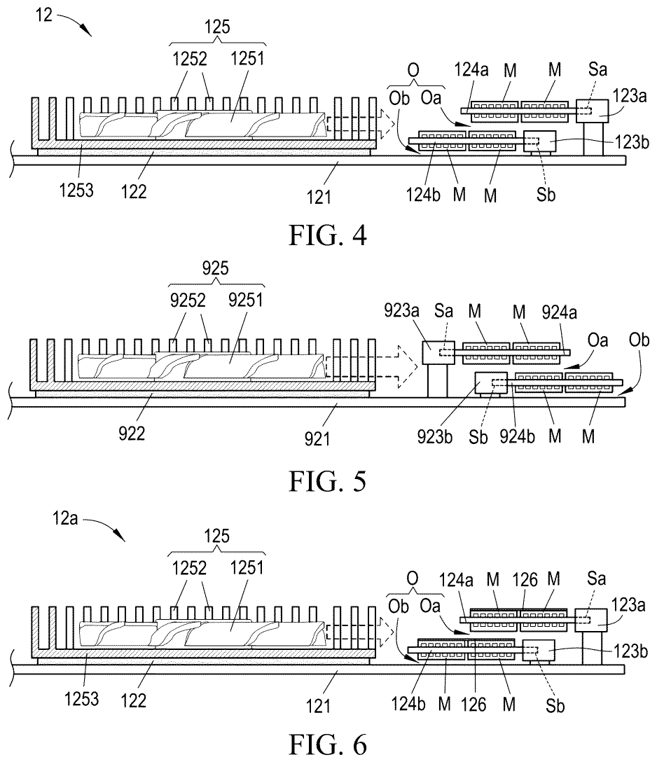

FIG. 1 is a schematic diagram of an electronic device 1 according to an embodiment of the present invention. FIG. 2 and FIG. 3 are respectively a three-dimensional schematic diagram and a schematic top view of a motherboard structure 12 of the electronic device 1 in FIG. 1. FIG. 4 is a schematic cross-sectional view of the motherboard structure 12 in FIG. 2.

Referring to FIG. 1 first, the electronic device 1 in this embodiment includes a computer case 11 and a motherboard structure 12. In addition, the electronic device 1 in this embodiment may further include a display screen 13, a keyboard 14, and a mouse 15. The motherboard structure 12 is arranged in the computer case 11, and the display screen 13, the keyboard 14, and the mouse 15 are electrically connected to the motherboard structure 12. The display screen 13, the keyboard 14, and the mouse 15 are devices well-known to a person skilled in the art, and details are not described herein.

As shown in FIG. 2 to FIG. 4, the motherboard structure 12 includes a circuit substrate 121, a processor 122, at least one adapter (two adapters 123a and 123b shown in the figure), at least one external card (two external cards 124a and 124b shown in the figure), and a heat dissipation module 125.

The circuit substrate 121 may be a printed circuit substrate (PCB). The processor 122 is arranged at the circuit substrate 121, and is electrically connected to the circuit substrate 121. Herein, the processor 122 may be a core control component of the electronic device 1, which is configured to control operation of the electronic device 1. For example, the processor includes a central processing unit (CPU) or a graphics processing unit (GPU).

The at least one adapter is arranged at the circuit substrate 121, and includes a slot facing the processor 122. The at least one external card is inserted into the slot of the at least one adapter, and the at least one external card and the circuit substrate 121 collectively define an opening facing the processor 122. Herein, the “opening” refers to a space collectively defined by the external card and the circuit substrate. However, if two or more external cards are arranged, the “opening” collectively defined by one of the external cards and the circuit substrate 121 may be divided into two by another external card, to form two secondary openings. Two adapters and two external cards are arranged in this embodiment, which are respectively adapters 123a and 123b, and external cards 124a and 124b respectively corresponding to the adapters 123a and 123b. The adapters 123a and 123b are respectively electrically connected to the external cards 124a and 124b. The adapters 123a and 123b are arranged (erected) side by side on the circuit substrate 121. The adapter 123a includes a slot Sa (in FIG. 4) facing the processor 122, and the external card 124a is inserted into the slot Sa of the adapter 123a. In addition, the adapter 123b includes a slot Sb (in FIG. 4) facing the processor 122, and the external card 124b is inserted into the slot Sb of the adapter 123b. Since the slots Sa and Sb of the adapters 123a and 123b face the processor 122, the external cards 124a and 124b may be respectively inserted into the slots Sa and Sb of the adapters 123a and 123b obliquely, so that the external card 124a and the external card 124b are stacked on each other.

In addition, the external card 124a and the circuit substrate 121 collectively define an opening O facing the processor 122. The external card 124b divides the opening O into two, to form two secondary openings Oa and Ob (in FIG. 2 or FIG. 3). Moreover, it should be emphasized that the slot Sa corresponding to the adapter 123a relatively far away from the processor 122 is relatively far away from the circuit substrate 121. Therefore, when the external cards 124a and 124b are inserted into the slots Sa and Sb of the adapters 123a and 123b, no interference occurs with each other, and the external cards 124a and 124b and the circuit substrate 121 can cooperatively define the secondary openings Oa and Ob facing the processor 122. In an embodiment, the external cards 124a and 124b each have a connecting finger corresponding to each of the slots Sa and Sb. The connecting fingers of the external cards 124a and 124b are respectively inserted into the slots Sa and Sb, and are electrically connected to the adapters 123a and 123b (and the processor 122).

The external cards 124a and 124b in this embodiment each are a memory card, for example, but not limited to a double data rate fifth generation synchronous dynamic random-access memory (DDR5 for short). Herein, the external card 124a is located between the adapter 123a and the heat dissipation module 125, and the external card 124b is located between the adapter 123b and the heat dissipation module 125. The external cards 124a and 124b in this embodiment each include an upper surface, a lower surface, and a plurality of memories M (for example, each include 16 memories M). The memories M are arranged on the upper surface and the lower surface of each of the external cards 124a and 124b. Specifically, each of the upper surface and the lower surface of the external card 124a is provided with two rows of memories M, with each row including 4 memories M. In other words, the upper surface of the external card 124a is provided with 8 memories M, and the lower surface is also provided with 8 memories M. In addition, each of the upper surface and the lower surface of the external card 124b is also provided with two rows of memories M, with each row including 4 memories M. In other words, the upper surface of the external card 124b is provided with 8 memories M, and the lower surface is also provided with 8 memories M.

The heat dissipation module 125 is arranged at the processor 122, to take away heat generated by the processor 122, and reduce a temperature of the processor 122. Herein, the heat dissipation module 125 includes a notch U facing the secondary openings Oa and Ob. The heat dissipation module 125 is adapted to generate an airflow flowing to the secondary openings Oa and Ob through the notch U. Specifically, the heat dissipation module 125 in this embodiment includes a fan 1251 and a set of heat dissipation fins 1252. A bottom 1253 (in FIG. 4) of the set of heat dissipation fins 1252 may be connected to the processor 122 through, for example, a thermally conductive adhesive (not shown). In addition, the set of heat dissipation fins 1252 further include a plurality of heat dissipation fins (1252). The heat dissipation fins (1252) are arranged on a periphery of the fan 1251, and the heat dissipation fins (1252) are arranged on the periphery of the fan 1251 from two opposite sides of the notch U. As shown in FIG. 3, a width of the notch U is less than widths of the secondary openings Oa and Ob.

Therefore, the heat generated by the processor 122 may be transferred to the set of heat dissipation fins 1252. An airflow generated by the fan 1251 flows toward the set of heat dissipation fins 1252, to dissipate the heat generated by the processor 122 to outside. In addition, the airflow generated by the fan 1251 may further flow toward the secondary openings Oa and Ob through the notch U, to dissipate heat of the memories M on the external cards 124a and 124b, thereby reducing temperatures of the memories M. Therefore, the heat dissipation module 125 not only may dissipate heat of the processor 122, and the heat dissipation module 125 may further reduce the temperatures of the memories M on the external cards 124a and 124b. Therefore, the motherboard structure 12 in this embodiment may have desirable heat dissipation efficiency.

A person skilled in the art may understand that the motherboard structure 12 may further include another element, unit, or module, for example, a capacitor, a resistor, a display card, a hard disk drive, and/or a power supply unit. These elements, units, or modules are well-known, and are not a focus of the present disclosure, and therefore are not described herein.

FIG. 5 is a schematic cross-sectional view of an existing motherboard structure. As shown in FIG. 5, an existing method of arranging adapters 923a and 923b on a circuit substrate 921 is causing slots Sa and Sb of the adapters 923a and 923b to respectively face away from a processor 922. Therefore, when external cards 924a and 924b are respectively inserted into the slots Sa and Sb of the adapters 923a and 923b, the adapters 923a and 923b are both located between a heat dissipation module 925 and the external cards 924a and 924b. Even if an airflow generated by the heat dissipation module 925 flows to the external cards 924a and 924b through a notch U, the airflow is blocked by the adapters 923a and 923b, and cannot flow through secondary openings Oa and Ob to dissipate heat of memories M. Therefore, as shown in Table I below, surface temperatures of memories M at positions #1-#4 on a lower surface of the external card 924a and memories M at positions #5-#8 on a lower surface of the external card 924b are all relatively high, where a lowest surface temperature is 54.2° C., and a highest surface temperature is 69° C.

TABLE I

| Memory position number | Temperature (° C.) |
|---|---|
| Memory at a position #1 | 60.3 |
| Memory at a position #2 | 69 |
| Memory at a position #3 | 60.5 |
| Memory at a position #4 | 60 |
| Memory at a position #5 | 55.2 |
| Memory at a position #6 | 56.9 |
| Memory at a position #7 | 54.2 |
| Memory at a position #8 | 54.9 |

However, referring to FIG. 4 again, in this embodiment, the adapters 123a and 123b are turned, so that the slots Sa and Sb of the adapters 123a and 123b face the processor 122. When the external cards 124a and 124b are respectively inserted into the slots Sa and Sb of the adapters 123a and 123b, the airflow generated by the heat dissipation module 125 may dissipate heat of the memories M through the notch U and the secondary openings Oa and Ob. Therefore, as shown in Table II below, surface temperatures of memories M at positions #1-#4 on a lower surface of the external card 124a at the same position and memories M at positions #5-#8 on a lower surface of the external card 124b at the same position are all lower than those of the memories in Table I, and do not exceed 50° C., and the lowest surface temperature may reach 42° C. Apparently, the method in the embodiment of FIG. 4 may further cause the memories M on the external cards 124a and 124b to produce desirable heat dissipation effects.

TABLE II

| Memory position number | Temperature (° C.) |
|---|---|
| Memory at a position #1 | 47.8 |
| Memory at a position #2 | 49.6 |
| Memory at a position #3 | 44 |
| Memory at a position #4 | 45.4 |
| Memory at a position #5 | 43.8 |
| Memory at a position #6 | 43.1 |
| Memory at a position #7 | 42 |
| Memory at a position #8 | 44.7 |

In addition, referring to FIG. 6, FIG. 6 is a schematic cross-sectional view of a motherboard structure 12a according to another embodiment of the present invention. The motherboard structure 12a in this embodiment is substantially the same as the motherboard structure 12 in the above embodiment. A main difference from the motherboard structure 12 is that the motherboard structure 12a in this embodiment may further include at least one heat dissipation film. The heat dissipation film is arranged at an external card. Herein, an example in which a heat dissipation film 126 is attached to memories M on an upper surface of an external card 124a, and another heat dissipation film 126 is attached to memories M on an upper surface of an external card 124b is used.

The heat dissipation film 126 may include a high thermal conductivity material, for example, but not limited to graphene, graphite, a carbon nanotube, aluminum oxide, zinc oxide, titanium oxide, boron nitride (BN), or a combination thereof, or another suitable high thermal conductivity material, to further improve heat dissipation efficiency of the memories M on the external cards 124a and 124b. In an embodiment, heat generated during operation of the memories M on the external cards 124a and 124b may be directly guided to a housing of the computer case 11 through the heat dissipation film.

Based on the above, in the motherboard structure and the electronic device of the present invention, the adapter is arranged at the circuit substrate, and includes the slot facing the processor. The external card is inserted into the slot, and the external card and the circuit substrate collectively define the opening facing the processor. The heat dissipation module is arranged at the processor, and includes the notch facing the opening. The heat dissipation module is adapted to generate the airflow flowing to the opening through the notch. Therefore, the above structural design causes the motherboard structure and the electronic device of the present invention to have desirable heat dissipation efficiency.

The above descriptions are merely examples but not limitations. Any equivalent modification or change to the present invention without departing from the spirit and scope thereof is included in the appended claims.

What is claimed is:

1. A motherboard structure, comprising:
A motherboard structure, comprising;
a processor, arranged at the circuit substrate;
at least one adapter, arranged at the circuit substrate, and comprising a slot facing the processor;
at least one external card, inserted into the slot, the at least one external card and the circuit substrate collectively defining an opening facing the processor; and
a heat dissipation module, arranged at the processor, and comprising a notch facing the opening, wherein the heat dissipation module is adapted to generate an airflow flowing to the opening through the notch.

2. The motherboard structure according to claim 1, wherein the external card is located between the adapter and the heat dissipation module.

3. The motherboard structure according to claim 1, wherein the external card comprises an upper surface, a lower surface, and a plurality of memories, the memories are respectively configured on the upper surface and the lower surface, and each of the memories comprises a double data rate fifth generation synchronous dynamic random-access memory.

4. The motherboard structure according to claim 1, wherein a number of the adapter is two, and the adapters are arranged side by side on the circuit substrate.

5. The motherboard structure according to claim 1, wherein the heat dissipation module comprises a fan and a plurality of heat dissipation fins, and the heat dissipation fins are arranged on a periphery of the fan from two opposite sides of the notch.

6. The motherboard structure according to claim 1, wherein a width of the notch is less than a width of the opening.

7. The motherboard structure according to claim 1, further comprising:
a heat dissipation film, arranged at the external card.

8. An electronic device, comprising:
a computer case; and
a motherboard structure, arranged in the computer case, and comprising:
a circuit substrate;
a processor, arranged at the circuit substrate; a processor, arranged at the circuit substrate;
at least one adapter, arranged at the circuit substrate, and comprising a slot facing the processor;
at least one external card, inserted into the slot, the at least one external card and the circuit substrate collectively defining an opening facing the processor; and
a heat dissipation module, arranged at the processor, and comprising a notch facing the opening, wherein the heat dissipation module is adapted to generate an airflow flowing to the opening through the notch.

9. The electronic device according to claim 8, wherein the external card is located between the adapter and the heat dissipation module.

10. The electronic device according to claim 8, wherein the external card comprises an upper surface, a lower surface, and a plurality of memories, the memories are respectively configured on the upper surface and the lower surface, and each of the memories comprises a double data rate fifth generation synchronous dynamic random-access memory.

11. The electronic device according to claim 8, wherein a number of the adapter is two, and the adapters are arranged side by side on the circuit substrate.

12. The electronic device according to claim 8, wherein the heat dissipation module comprises a fan and a plurality of heat dissipation fins, and the heat dissipation fins are arranged on a periphery of the fan from two opposite sides of the notch.

13. The electronic device according to claim 8, wherein a width of the notch is less than a width of the opening.

14. The electronic device according to claim 8, wherein the motherboard structure further comprises a heat dissipation film, and the heat dissipation film is arranged at the external card.
